(19) United States
(12) Patent Application Publication
(10) Pub. No.: US 2012/0260847 A1
(43) Pub. Date: Oct. 18, 2012

(54) AMORPHOUS SILICON CRYSTALLIZATION USING COMBINED BEAMS FROM MULTIPLE OSCILLATORS

(75) Inventor: Paul Christiaan VAN DER WILT, Goettingen (DE)

(73) Assignee: Coherent GmbH, Gottingen (DE)

(21) Appl. No.: 13/222,956

(22) Filed: Aug. 31, 2011

Related U.S. Application Data
(60) Provisional application No. 61/474,600, filed on Apr. 12, 2011.

(51) Int. Cl. C30B 13/24

(52) U.S. Cl. 117/37; 117/222

(57) ABSTRACT

In a silicon crystallization method, a pulse is delivered from each of two excimer lasers. The duration of one of the pulses is extended in a pulse-duration extender to a duration significantly longer than that of that of the other. The extended-duration and other pulses are delivered along a common path. The other pulse temporally overlaps the extended-duration pulse after delivery of the extended-duration pulse begins. The silicon is preheated by the extended-duration before being melted by the combined pulses during the temporal overlap period.

### PRIORITY CLAIM

This application claims priority of U.S. Provisional Application No 61/474,600 filed Apr. 12, 2011, assigned to the assignee of the present invention, and the complete disclosure of each of which is hereby incorporated by reference.

### TECHNICAL FIELD OF THE INVENTION

The present invention relates in general to silicon (Si) crystallization using laser radiation pulses. The invention relates in particular to temporal shaping of the laser radiation pulses for optimizing the silicon crystallization.

### DISCUSSION OF BACKGROUND ART

Silicon crystallization is a step that is often used in the manufacture of thin-film transistor (TFT) active-matrix LCDs, and organic LED (AMOLED) displays. The crystalline silicon forms a semiconductor base, in which electronic circuits of the display are formed by conventional lithographic processes. Commonly, crystallization is performed using a pulsed laser beam shaped in a long line. In this process, a thin layer of amorphous silicon on a glass substrate is repeatedly melted by pulses of laser radiation while the substrate (and the silicon layer thereon) is translated relative to a delivery source of the laser-radiation pulses. Melting and re-solidification (re-crystallization) through the repeated pulses take place until a desired crystalline microstructure is obtained in the film.

Optical elements are used to form the laser pulses into a line of radiation, and crystallization occurs in a strip having the width of the line of radiation. Every attempt is made to keep the intensity of the radiation pulses highly uniform along the line. This is necessary to keep crystalline microstructure uniform along the strip. A favored source of the optical pulses is an excimer laser, which delivers pulses having a wavelength in the ultraviolet region of the electromagnetic spectrum. The above described crystallization process, using excimer-laser pulses, is usually referred to as excimer-laser annealing (ELA).

The ELA process is usually performed at a radiation energy density at which near complete melting of the silicon layer takes place. In most locations, the film is molten throughout the thickness of the layer. However, small solid portions remain that subsequently seed laterally growing crystal grains. During the repetitive radiation at this energy density, a microstructure evolves having a surface topology dictated by the wavelength of the light. This topology results from optical interference effects and this phenomenon has been described as laser-induced periodic surface structures (LIPSS). During the process, a grain-structure evolves that matches the surface topology, i.e., grains having a dimension similar to the wavelength of the pulse-radiation. The process energy density at which the desired grain structure is obtained is often referred to as the optimum energy density (OED).

The process is a delicate one. By way of example, high energy pulses may result in so-called shot marks (shot mura) in the film structure that may also be visible in the display. In an extreme case, a high energy pulse may result in radiation above the complete melting threshold (CMT) of the film, as a result of which nucleation and growth of small defective grains takes place. Generally, any energy-density variation along the length of the line may result in lines parallel to the scan (scan-mura). A very schematic illustration of various melting regimes is presented in FIGS. 1A-B, FIGS. 2A-B, and FIGS. 3A-B. In each pair, the “A” drawing schematically depicts a melted (or partially melted) layer, and the “B” drawing schematically depicts the crystal structure of the layer after solidification. The substrate is not shown. Radiation is delivered from the top. The width of the drawings corresponds to a small section within the width of the line of radiation.

In FIG. 1A, the layer is incompletely melted in a single pulse and the molten zone does not extend completely through the layer thickness. This leaves some solid crystalline microstructure from which vertical crystal growth occurs on solidification, as indicated in FIG. 1B. Thus-obtained material is fine grained, and, due to a high density of crystal defects will have poor electronic properties.

In FIG. 2A, melting is nearly complete. The molten zone extends from top to bottom of the layer except for a few remaining portions of the solid microstructure. This causes lateral crystal growth on solidification as indicated in FIG. 2B. Thus obtained material consists of large crystals, and, due to a low density of crystal defects, the material allows for high performance TFTs.

In FIG. 3A, melting has been complete and crystal nuclei have begun to form in the under-cooled molten zone. Typically material obtained from this nucleation process has a very high defect density and devices made from the material will have poor electronic properties.

It has been found that the temporal intensity profile (“pulse shape”) of irradiating pulses influences the occurrence of mura. Pulse shape is often optimized to reduce shot mura. However, this optimization is usually performed empirically, and can lead to different outcomes. Nevertheless, some simple guidelines in optimizing pulse-shape have been developed by practitioners of the art.

Based on simple thermal considerations, it can be argued that a short pulse-duration is preferred. Longer pulse-durations make it more difficult to effect the preferred incomplete or near complete melting of the film with a single pulse, as the heat diffusion length becomes very large. The typical temporal pulse-profile of a xenon chloride (XeCl) excimer-laser, which is a super-atmosphere gas-discharge laser, consists of two peaks (often referred to as “humps”). The FWHM duration of the first peak (hump) is typically less than 30 ns. The peak intensity of the second peak is typically about equal to or less than 50% of the first peak, and depends, inter alia, on lasing-gas mixture, repetition rate, gas aging, and discharge-pulse voltage.

FIG. 4 is a graph schematically illustrating calculated melt depth (bold curves) and beam intensity (fine curves) and as a function of time for prior-art excimer laser pulses having a wavelength of 308 nanometers (nm) in a silicon layer having a thickness of 100 nm. One pulse has a first-peak to second-peak intensity ratio of 50% (solid curves). The other has a first-peak to second-peak intensity ratio of 20% (dashed curves). In each case, the pulse-energy density is just below the complete-melting threshold.

It can be seen that when the intensity of the second peak is low, deepest melting occurs on the first peak. However, when the intensity of the second peak is high, deepest melting occurs on the second peak, even though melting may have already started on the first peak. Such a shift in the details of the melting and solidification is expected to lead to different outcomes of the cumulative crystallization process. By way of example, the cumulative microstructure evolution may progress at a different rate depending on intensity of the second peak. Thus, shifts in the ratio between the two peaks, as, for example, could occur as a result of gas aging, might bring about shifts in the optimum process condition such as the OED. Further, the stability of the process, or in other words the process window, may be affected by such shifts.

ELA technology is currently being considered for larger displays such as large-screen AMOLED TV displays. In order for this to be commercially effective, longer lines of radiation will be required than are currently the norm. A problem, however, is that this will require more power per pulse than can be delivered by a single excimer laser. One means of overcoming this problem would be to combine pulses from two or more excimer lasers. Simultaneous triggering of the lasers could be used to create a combined pulse having essentially the same pulse shape as a single pulse, i.e., a pulse with first and second peaks, as described above. A potential advantage may be that the pulse-to-pulse fluctuation of the combined pulse becomes less than that of the individual pulses, resulting in fewer high-energy pulses which lead to shot mura.

A problem in realizing a consistent pulse-combination is that there is a limit to the accuracy with which the two or more lasers can be triggered. This triggering inaccuracy is usually referred to by practitioners of the art as jitter. An exemplary state-of-the-art value of the jitter is about 5 nanoseconds (ns) for high pulse repetition rate (PRF) operation of an excimer laser, for example, about 500 kilohertz (kHz) or more. The jitter can be less for lower-PRF operation.

In experiments at low PRF, wherein the delay between two pulses being combined was systematically varied to smooth the intensity profiles of the combined pulse, the OED was observed to shift upwards by more than 2% for a delay of 5ns and more than 4% for a delay of 10 ns. These values indicate that a variation of the intensity profile of the combined pulse as a function of jitter exists that could be unacceptable for manufacturing. If the delay time was selected such that the first peak of the delayed pulse began to overlap with the second peak of the first pulse (between about 40 ns and 50 ns delay), a pulse-profile in which most energy is combined into a single intense peak was again created. In this condition, the OED shift may actually be very limited. However, at this condition, the pulse profile was still very sensitive to jitter, and, furthermore, also became sensitive to differences between the first pulse-profile and the second pulse-profile, for example, having a different energy or different peak-ratio.

In other words, whereas simultaneous triggering of pulses reduces the pulse-to-pulse fluctuation, delayed triggering to smooth the shape of a combined pulse profile may actually result in worse pulse-to-pulse fluctuation in the combined pulse than that of the individual pulses being combined. There is a need for a method of forming a combined pulse which can minimize OED shift while avoiding sensitivity of the combined pulse to pulse-to-pulse variation and jitter.

### SUMMARY OF THE INVENTION

In one aspect of the present invention a method of crystallizing a silicon layer, comprises delivering a first laser radiation pulse having a first pulse duration and a first peak intensity from a first laser and a second laser radiation pulse having a second duration and a second peak intensity from a second laser. The duration of the first laser pulse is extended in a pulse-duration extender to a third duration significantly longer than the second duration, thereby reducing the first peak intensity to a third peak intensity. The second-duration and third-duration pulses are combined, temporally overlapping. Combination of the second duration pulse is delayed such that the temporal overlap occurs at a predetermined time following initiation of the third-duration pulse. The temporally overlapping second-duration and third-duration pulses are projected onto the silicon layer. The second and third peak intensities are selected such that when the temporally overlapping second-duration and third-duration pulses are projected onto the silicon layer, the silicon layer is preheated by the third-duration pulse before being melted during the temporal overlap. In a preferred embodiment of the method, the lasers are excimer lasers. The synchronization of the pulse delivery and delivery delay is controlled by a trigger mechanism common to the two lasers.

### BRIEF DESCRIPTION OF THE DRAWINGS

FIG. 1A and FIG. 1B are cross section-views schematically illustrating one prior-art melting and re-crystallization regime for a silicon layer with melting being sufficiently incomplete that a crystal microstructure remains at the base of the silicon layer.

FIG. 2A and FIG. 2B are cross section-views schematically illustrating another one shot prior-art melting and re-crystallization regime for a silicon layer, with melting mostly complete, but wherein portions of the crystal microstructure of FIG. 1A remains at the base of the silicon layer resulting in lateral crystal growth with an irregular period.

FIG. 3A and FIG. 3B are cross section-views schematically illustrating a preferred prior-art melting and re-crystallization regime for a silicon layer similar to the regime of FIGS. 2A-B but with melting being totally complete before re-crystallization begins.

FIG. 4 is a graph schematically illustrating calculated melt-depth in a silicon layer as a function of time, for two prior-art laser pulse-forms.

FIG. 5 schematically illustrates a preferred embodiment of apparatus in accordance with the present invention, including first and second lasers delivering first and second pulses, a trigger arrangement for delivering delay of the second pulse with respect to the first pulse, a pulse-duration expander (PEX) arranged to expand (stretch) the duration of the first pulse, and a beam-combiner arranged to combine the stretched first pulse with the delayed second pulse to form a combined pulse having a temporal intensity-profile in accordance with the present invention.

FIG. 6 is a graph schematically illustrating intensity as a function of time for a stretched first pulse, a delayed second pulse, and a combination of the two, in the apparatus of FIG. 5, with the combined-pulse intensity depicted in half-scale compared with the intensity of the stretched first and delayed second pulses.

FIG. 6A is a graph similar to the graph of FIG. 6 but wherein the intensity of the combined pulses is depicted on the same scale as that of the stretched first and delayed second pulses.

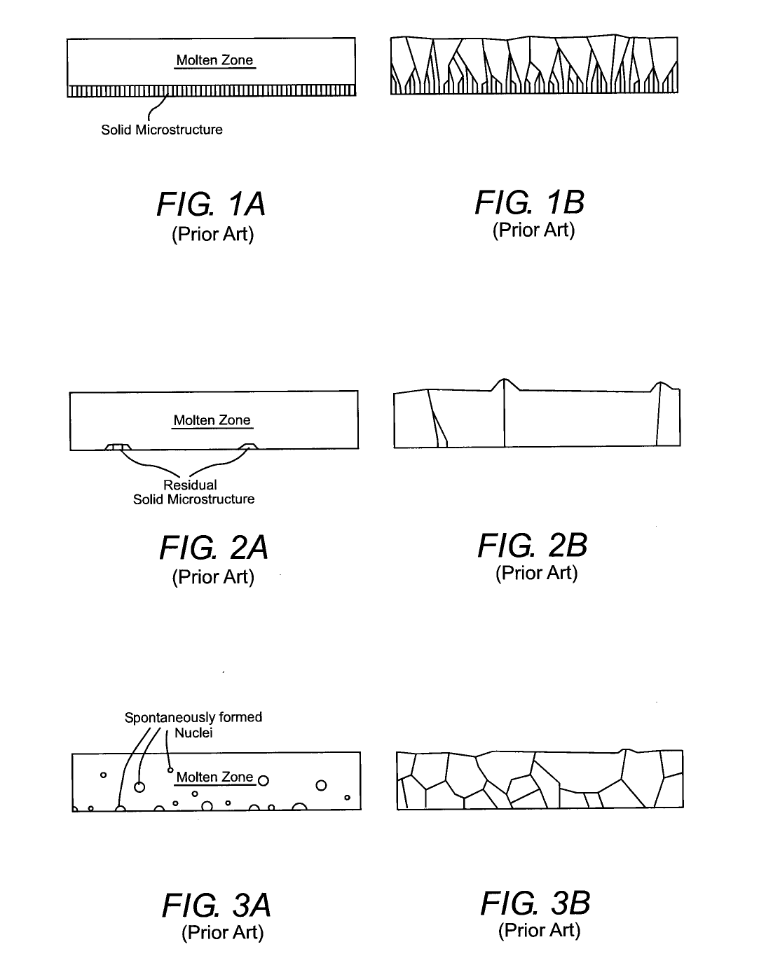

### DETAILED DESCRIPTION OF THE INVENTION

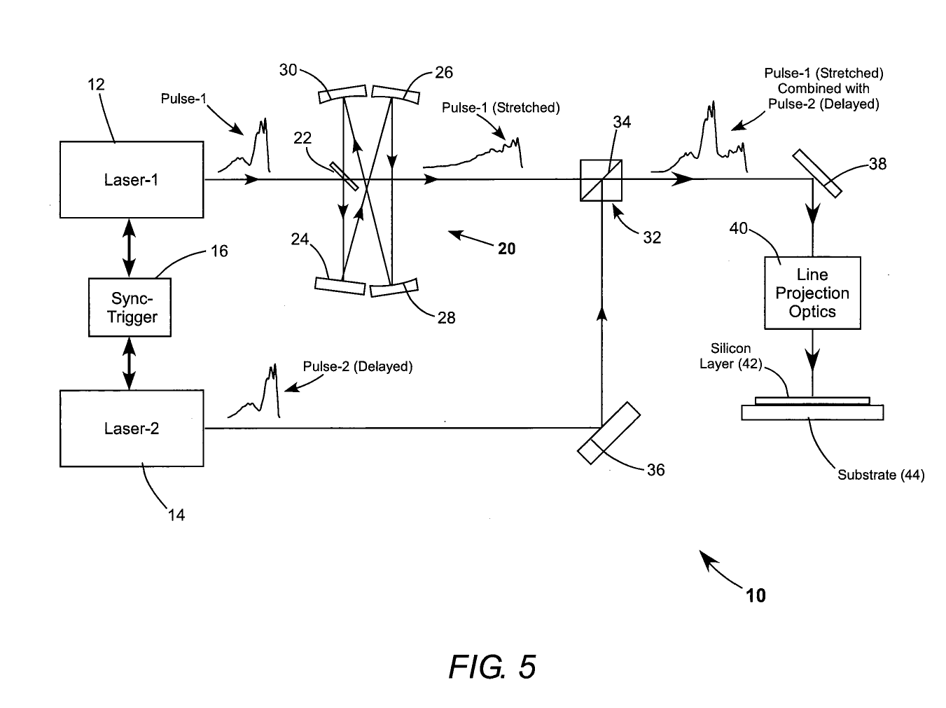

Continuing with reference to the drawings, FIG. 5 schematically illustrates one preferred embodiment 10 of apparatus in accordance with the present invention. Apparatus includes two excimer lasers 12 and 14 (laser-1 and laser-2), each delivering a train of radiation pulses at nominally the same PRF. For purposes of this description, only one pulse delivered from each train thereof is considered. These pulses are designated pulse-1 (from laser-1) and pulse-2 (from laser 2). Here, the lasers are synchronized and triggered by a synchronization control unit 16 such that the delivery of pulse -2 is delayed with respect to the delivery of pulse-1. The intensity as a function of time of the pulses is depicted with the time-axis increasing from right to left to correspond with the propagation direction of the pulses. Methods of synchronizing two excimer lasers are well known in the art. A preferred method is described in detail in U.S. patent application Ser. No. 12/852,864, filed Sep. 17, 2010, assigned to the assignee of the present invention, and the complete disclosure of which is hereby incorporated by reference.

Pulse-1 is intercepted by a pulse-duration expander (PEX) 20, including a plane beam-splitting mirror (beamsplitter) 22 (which is partially reflective and partially transmissive at the wavelength of the pulses) combined with a plane mirror 24 and concave mirrors 26, 28, and 30. A portion of pulse-1 is transmitted by mirror 22 and the remaining portion is reflected from the other mirrors (in sequential numeric order) back to mirror 22, where the remaining portion is divided into reflected and transmitted portions. Mirrors 24, 26, 28, and 30 are configured and arranged such that the beam size of the pulse is the same at each incidence thereof on mirror 22.

The reflected portion of the pulse from mirror 30 exits the PEX on the same path as the originally-transmitted portion. The new transmitted portion makes a second sequence of reflections back to mirror 20 where pulse division into reflected and transmitted portions again takes place. This sequence is repeated until there no significant pulse energy remaining in the PEX. By selecting a particular value for the reflection and transmission of mirror 22 and the path length (optical delay time) around the PEX, the originally-transmitted and subsequently-reflected pulse portions can be temporally overlapped to form a new pulse (stretched pulse-1) which has a smoother temporal profile and lower peak intensity than the original pulse. The stretched pulse will have nominally the same energy as the original pulse, less that which is lost to scatter and absorption in the PEX.

Only sufficient description of PEX 20 is provided to illustrate the function of the PEX in the inventive apparatus. A more detailed description of such a PEX is not necessary to understand principles of the present invention and, accordingly, is not presented herein. A detailed description of a PEX such as PEX 20, and a description of more complex PEX forms, with different pulse-shaping possibilities, is provided in U.S. Pre-Grant Publication No. 2006/0216037, and U.S. Pat. No. 7,035,012, each of which is assigned to the assignee of the present invention, and the complete disclosure of each of which is hereby incorporated herein by reference.

Continuing with reference to FIG. 5, stretched pulse-1 and original pulse-2 are combined temporally overlapping by a beam combining arrangement 32. Any prior-art beam-combining arrangement may be used including one or more polarization sensitive elements. Here, for simplicity of illustration, a single element is depicted. One preferred arrangement is described in U.S. Pat. No. 7,408,714, assigned to the assignee of the present invention, and the complete disclosure of which is hereby incorporated by reference. As seen in the '714 patent, the beams from the two lasers can be directed initially on separate paths and finally combined at the target.

Pulse-2 is delayed such that the leading edge thereof occurs later than the leading edge of stretched pulse-1. The temporally-overlapping (combined) pulses are directed by a mirror 38 into line-projection optics 40 which project the combined pulses onto a silicon layer 42 being crystallized, the layer, of course being supported on a substrate 44.

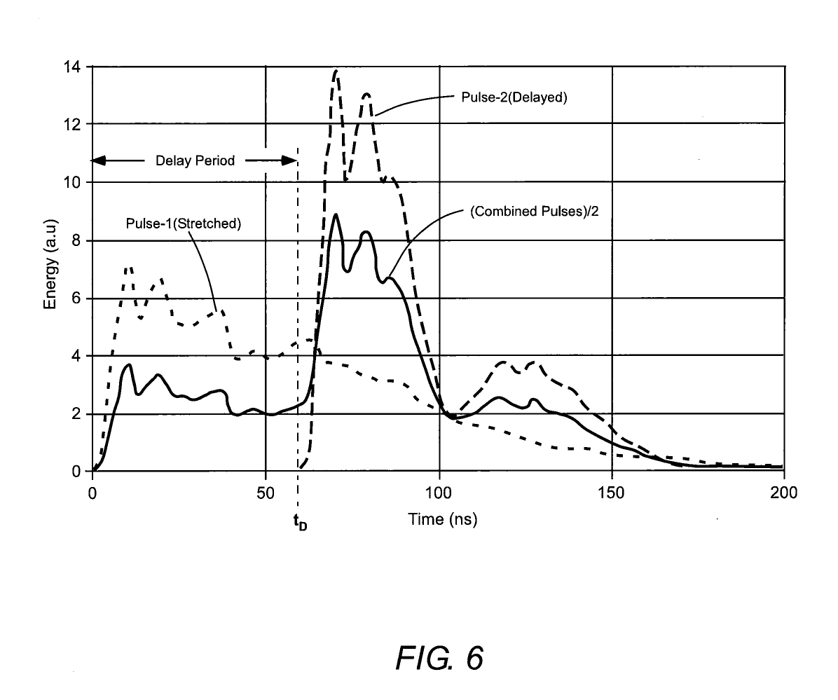

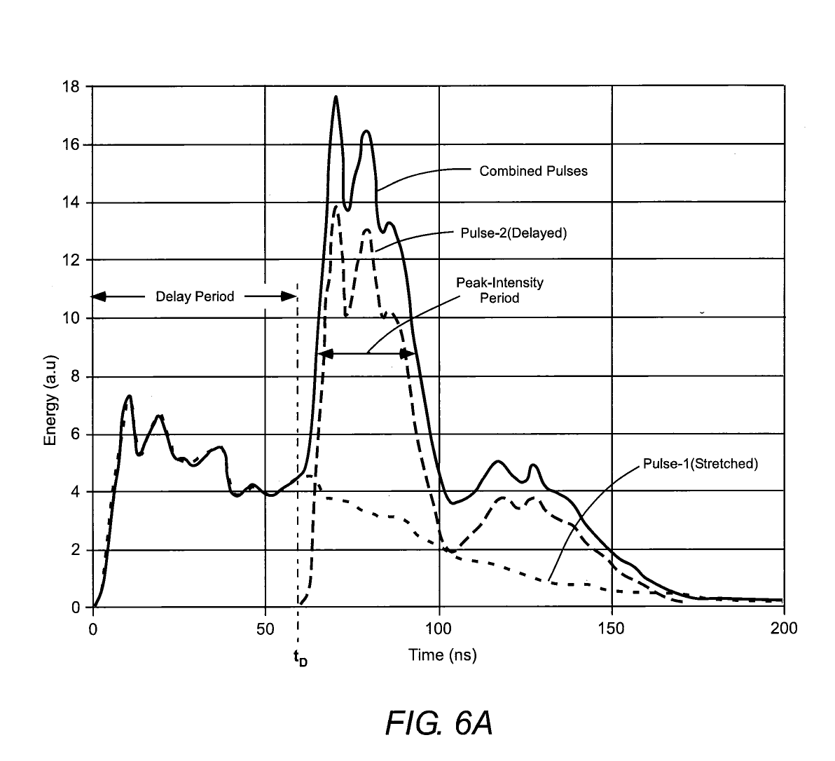

Stretching of pulse-1 and the delay of pulse-2 is arranged such that the temporally combined pulse has a broad base-level of intensity which, when initially projected onto silicon layer 42, has insufficient energy to initiate melting the silicon layer. Superimposed on the base level of intensity is an intensity-peak resulting from the contribution of pulse-2 to the pulse-combination. This intensity peak has sufficient energy to cause the desired incomplete or near complete melting of the silicon layer. An example of the pulse-combination is described below with reference to FIG. 6 and FIG. 6A.

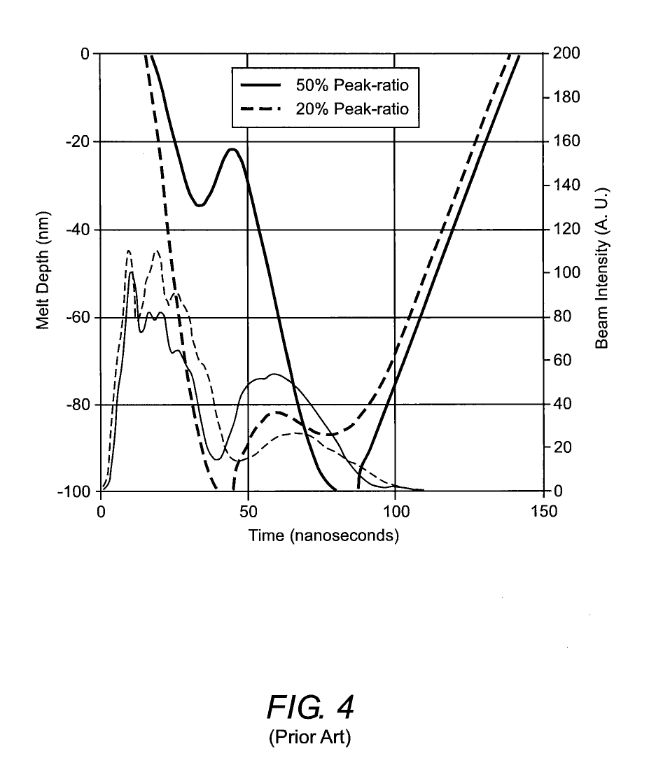

Here, it is assumed that each of the lasers 12 and 14 delivers an above-discussed two-peak pulse having a peak-ratio of about 20%, wherein melting would typically occur primarily through the first peak, with the second peak merely protracting re-crystallization, as depicted in FIG. 4. It is assumed that mirror 22 of PEX 20 has a reflectivity and transmission of 50% and that the round-trip delay of the PEX is 27.0 ns.

It can be seen that these PEX parameters stretch and smooth pulse-1 such that there is no prominent peak-intensity in the stretched pulse, with intensity falling gradually over a period of about 175 ns. Pulse-2 pulse is a delayed by a period t_{D}, in this case, by about 60.0 ns. The delay can be created entirely by suitable triggering if the optical path of the pulses to the point of combination is the same. Alternatively, the delay can be created by some combination of pulse-triggering delay and optical path difference, or entirely by the optical path difference. An optical-path difference of about 30.0 centimeters (cm) is equal to a delay of 1.0 ns.

In FIG. 6, the intensity profile of the combination pulse is depicted with intensity in half-scale to better show the profiles of the stretched and original pulses being combined. In FIG. 6A, the intensity of all pulses is on the same-scale. It can be estimated from the graphs that the FWHM duration of the stretched pulse is about three-times that of the first (melting-effective) peak of the second pulse.

The combined pulse is characterized by a very prominent peak-intensity region over a background region, with the peak region having a duration of about 30 ns, which is about one-fifth of the total period of radiation delivery. In practice, it is arranged such that the prominent peak region is the only region in which intensity is sufficient to initiate significant melting, with the remaining background radiation predominantly used for preheating the layer before melting is initiated, or, less preferably, for protracting the re-crystallization after the melting.

In an experiment, a pulse similar to the combined pulse of FIG. 6 gave an OED that was only about 2% higher than that of a single un-stretched pulse. This compares with a more than 12% increase that was obtained with two simultaneously triggered pulses that were each led through a PEX before being combined; and a more than 6% increase with a stretched pulse-1, but zero delay in combining un-stretched pulse 2, i.e., with no pre-heating period. With pulse-2 delayed by 80 ns, the OED was the same (2% higher than that of an un-stretched pulse) as with the 60 ns-delay; and with a delay of 100 ns, the OED was still only about 4% higher. This indicates that there is a wide window of combination-delay in which OED is almost constant, but there must be some pre-heating period which is a significant portion of the total radiation-delivery period. For excimer lasers having a typical pulse width on the order of 100 ns un-stretched and 150 ns stretched, the delay of the second pulses is preferably between 20 and 100 ns and more preferably between 40 and 80 ns.

It is emphasized that melting with the above-described inventive pulse-intensity profile is dictated by the short intense peak from the unstretched pulse. Pre-heating occurs as a result of the smoothed pulse from the first laser, and, as a result, a lower intensity-peak is sufficient to induce the required near-complete melting for a single pulse. A trace of the second peak of the un-stretched pulse is still present in the background, but has a sufficiently low energy that deepest melting is ensured to occur as a result of the first-peak intensity.

Nevertheless, it may be beneficial to further reduce the intensity of the second peak or eliminate a second peak altogether. Reducing the second-peak intensity of the un-stretched pulse may be accomplished by including in laser 14 (laser-2) a gas-mixture that gives a lower second peak. Alternatively, hardware may be used to divert away the energy from the pulsing electronics at the time the second peak would otherwise be created.

Further, laser 12 (laser-1), delivering the pulse to be stretched, may be optimized such that the pulse to be stretched has a smoother profile than that of the 20% peak-ratio pulse discussed above. For example, a higher second peak may be desirable in the pulse to be stretched so that a PEX with smaller reflectivity and/or delay may be sufficient to create a smooth pulse profile. In addition, two PEX's in series, or a double-pass PEX as described in the above referenced '6037 publication may be used. It is also possible to combine outputs of more than two lasers with pulses optimized and shaped in different ways to further optimize the intensity-profile of the combined pulses. Those skilled in the art may use these and any other means to achieve the inventive pulse profile, without departing from the spirit and scope of the present invention. Whatever means are used to achieve the inventive pulse profile, the intensity profile should still be such, that, when the pulse is projected on the silicon layer, melting still predominantly occurs on the short high-intensity peak, with the initial pre-heating stage not leading to melting. The energy-ratio between the pre-heating and the melting stages accordingly should thus not exceed a certain value. Heat-flow simulations as well as transient reflectivity data indicate that for regular pulse profiles, deepest melting can easily occur on the second hump when the intensity thereof is even less than 50% of that of the first hump. To avoid melting on the first hump altogether, a larger ratio should be used, for example 75% intensity of the second hump or even a 1:1 ratio.

While heat-flow simulations and transient reflectance measurements can be instrumental in understanding the exact onset of melting for smooth homogeneous films, these methods become less meaningful for polycrystalline films having surface roughness and high degree of heterogeneity. In other words, the maximum ratio between the pre-heating and the melting pulse should be established experimentally by evaluating the material.

In summary, the present invention has been described in terms of a preferred and other embodiments. The invention is not limited, however, to the embodiments described and depicted. Rather, the invention is defined by the claims appended hereto.

What is claimed is:

1. A method of crystallizing a silicon layer, comprising the steps of:
delivering a first laser radiation pulse having a first pulse duration and a first peak intensity from a first laser and a second laser radiation pulse having a second duration and a second peak intensity from a second laser;
extending the duration of the first laser pulse in a pulse-duration extender to a third duration significantly longer than the second duration, thereby reducing the first peak intensity to a third peak intensity;
combining the second-duration and third-duration pulses, temporally overlapping;
delaying combination of the second duration pulse such that the temporal overlap occurs at a predetermined time following initiation of the third-duration pulse; and
projecting the temporally overlapping second-duration and third-duration pulses onto the silicon layer the second and third peak intensities being selected such that when the temporally overlapping second-duration and third-duration pulses are projected onto the silicon layer, the silicon layer is preheated by the third-duration pulse before being melted during the temporal overlap.

2. The method of claim 1, wherein the first and second lasers are excimer lasers and the first and second laser pulses have a wavelength in the ultraviolet region of the electromagnetic spectrum.

3. The method of claim 2 wherein the predetermined time delay is between 20 ns and 100 ns.

4. The method of claim 2 wherein the predetermined time delay is between 40 ns and 80 ns.

5. A method of crystallizing a layer of silicon comprising:
generating a first pulse of laser radiation from a first laser;
temporally extending the first pulse;
generating a second pulse of laser radiation from a second laser; and
exposing the layer of silicon to a combination of the first and second pulses, wherein the start of the second pulse is delayed with respect to the first pulse so that energy delivered to the silicon in the initial portion of the exposure is less than during subsequent portion of the exposure.

6. The method of claim 5 wherein the first and second lasers are excimer lasers.

7. The method of claim 6 wherein the second pulse is delayed with respect to the first pulse between 20 ns and 100 ns.

8. The method of claim 6 wherein the second pulse is delayed with respect to the first pulse between 40 ns and 60 ns.

9. A method of crystallizing a layer of silicon comprising:
generating a first pulse of laser radiation from a first laser;
temporally extending the first pulse;
generating a second pulse of laser radiation from a second laser a predetermined time period after the start of the first pulse so the second pulse is delayed with respect to the first pulse; and
exposing the layer silicon to a combination of the first and second pulses, wherein the delay of the second pulse is selected so that the energy delivered to the silicon in the initial portion of the exposure is less than during subsequent portion of the exposure.

10. The method of claim 9 wherein the first and second lasers are excimer lasers.

11. The method of claim 10 wherein the second pulse is delayed with respect to the first pulse between 20 ns and 100 ns.

12. The method of claim 10 wherein the second pulse is delayed with respect to the first pulse between 40 ns and 60 ns.

13. A method of crystallizing a layer of silicon using pulses from three or more lasers comprising the steps of:
generating laser pulses from said at least three lasers;
temporally extending the pulses from at least one of the lasers; and
exposing the layer silicon to a combination of the pulses from the at least three lasers, wherein the start of one of the pulses of the lasers that has not been temporally extended is delayed with respect to the start of the temporally extended pulse so that the energy delivered to the silicon in the initial portion of the exposure is less than during subsequent portion of the exposure.

14. The method of claim 13 wherein the lasers are excimer lasers.

15. An apparatus for crystallizing a layer of silicon comprising:
a first excimer laser for generating first laser pulses;
a second excimer laser for generating second laser pulses;
a control system for controlling the triggering of the lasers;
a pulse extender for extending the first laser pulses; and
optics for exposing the silicon to a combination of the first extended pulses and second non-extended laser pulses, and wherein the control system operates to delay the generation of the second pulses with respect to the generation of the first pulses in a manner so that the energy delivered to the silicon in the initial portion of the exposure of each set of combined pulses is less than during subsequent portion of the exposure of each set of combined pulses.

16. The apparatus of claim 15 wherein the second pulses are delayed with respect to the first pulses between 20 ns and 100 ns.

17. The apparatus of claim 15 wherein the second pulses are delayed with respect to the first pulses between 40 ns and 60 ns.
